(19) United States
(12) Patent Application Publication
(10) Pub. No.: US 2005/0230704 A1
(43) Pub. Date: Oct. 20, 2005

(54) Self-scanning light-emitting element array and driving method of the same

(76) Inventor: Seiji Ohno, Minato-ku (JP)

Correspondence Address: RATNERPRESTIA, P O BOX 980, VALLEY FORGE, PA, 19482-0980, US

(21) Appl. No.: 11/103,226

(22) Filed: Apr. 11, 2005

(30) Foreign Application Priority Data
Apr. 14, 2004 (JP) 2004-118759

(51) Int. Cl. H01L 29/417; H01L 29/74

(52) U.S. Cl. 257/113

(57) ABSTRACT

A self-scanning light-emitting element array is driven such that, if a current supply line for a light-emitting element is broken, a light-emitting element neighboring failed light-emitting element continues to operate. In first time period turned-on states of the neighboring two thyristor overlap when the turned-on state is transferred in the transfer portion by the two-phase clock pulses; a second time period is provided after the first period, during which the light-emitting thyristor corresponding to the turned-on thyristor in the transfer portion is lighted by the light-emitting signal; in a third time period, after the second time period, a turned-off transfer thyristor for the turned-on thyristor is turned on and the lighted thyristor in the light-emitting portion is lighted out. The second time period has a length in which the thyristor having the broken line neighboring the failed thyristor is lighted.

### BACKGROUND OF THE INVENTION

1. Field of the Invention

The present invention relates to a method for driving a self-scanning light-emitting element array, particularly to a method for driving a self-scanning light-emitting element array in which an effect to an image is not caused even if there is a thyristor which is not lighted in a light-emitting portion due to the breakage of a current supply line for thyristors in the light-emitting portion.

2. Related Art

A light-emitting element array in which a plurality of light-emitting elements are integrated on the same substrate is utilized as an optical writing head for an optical printer and the like with combining it to a driving IC. The inventors of the present invention have interested in a three-terminal light-emitting thyristor having a pnpn-structure as a component of the self-scanning light-emitting element array, and have already filed several patent applications (see Japanese Patent Publication Nos. 1-238962, 2-14584, 2-92650, and 2-92651) showing that a self-scanning operation for the thyristors in a light-emitting portion may be realized. These publications have disclosed that such a self-scanning light-emitting element array has a simple and compact structure for a light source of a printer, and has smaller arranging pitch of light-emitting elements.

The inventors have further provided a self-scanning light-emitting device having such structure that a transfer portion including switch elements (light-emitting thyristors) array is separated from a light-emitting portion including light-emitting elements (light-emitting thyristors) array (see Japanese Patent Publication No. 2-263668).

Referring to FIG. 1A, there is shown an equivalent circuit diagram of a self-scanning light emitting array in which a transfer portion and light-emitting portion are separated. The self-scanning light-emitting element array comprises a transfer portion including thyristors S₁, S₂, S₃ . . . and a light-emitting portion including thyristors L₂, L₂, L₃ . . . . The structure of the transfer portion utilizes a diode-coupling system, i.e., the neighbored gates of the thyristors S₁, S₂, S₃ . . . are connected by diodes D₁, D₂, D₃ . . . , respectively. A power Supply VGA is connected to gate g₁, g₂, g₃ . . . in the transfer portion through gate load resistors R_{g1}, R_{g2}, R_{g3}, respectively. Respective gates g₁, g₂, g₃ . . . of the thyristors S₁, S₂, S₃ . . . are also connected corresponding gates g′₁, g′₂, g′₃ of the thyristors L₁, L₂, L₃ in the light-emitting portion through resistors Rₚ₁, Rₚ₂, Rₚ₃ . . . . Respective cathodes of the thyristors in the transfer portion are connected alternately to φ1 line 12 and φ2 line 14.

Current limiting resistors R1 and R2 are inserted in the φ1 line 12 and φ2 line 14, respectively.

Respective cathodes of the thyristors L₁, L₂, L₃ . . . in the light-emitting portion are connected to a light-emitting signal φ_{I} line 16. A current limiting resistor R_{I} is inserted in the φ_{I} line 16.

By driving the self-scanning light-emitting element array thus structured, a thyristor in the light emitting portion designated by the turned-on state of a thyristor in the transfer portion driven by two-phase clock pulses φ1 and φ2 is lighted or lighted out to make an image.

In FIG. 1B, there shown High/Low-level of the clock pulses φ1, φ2 and the light-emitting signal φ_{I}, turned-on/turned-off state of the thyristors in the transfer portion, and lighted/lighted out state of the thyristors in the light-emitting portion. As shown in FIG. 1B, a time period during which both clock pulses φ1 and φ2 are at Low-level is shown by tₐ(=t₃−t₂), a time period until when the light-emitting signal φ_{I} becomes Low-level after any of clock pulses φ1 and φ2 becomes High-level is shown by t_{b}(=t₄−t₃), and a transfer period is shown by T(=t₅−t₂). Herein, a time when the light-emitting signal φ_{I} becomes High-level is set equally to a time when next clock pulse becomes Low-level to increase a light-emitting period. As a result, the light-emitting time period is equal to (T−tₐ−t_{b}).

As an example, a transfer period T=t₅−t₂=500 ns, a time period tₐ=t₃−t₂=20 ns, and a time period t_{b}=t₄−t₃=20 ns.

As a line for supplying a current to the thyristors in the light-emitting portion is thin in its width and the density of a current through it is large, there is a possibility of the breakage of the line due to an electro-migration. In a conventional drive method, the transfer operation becomes unstable when the breakage of a line is caused, and the thyristors succeeding the breakage point in a transfer direction in the light-emitting portion may not be lighted. In such a case, an image defect will be caused in which a part of an image is not printed across several mili meters in width (i.e., white stripe) for the worst case, which depends on the breakage point. This defect will be remarkable in a printed image. As a color printer having a printing density of 1200 dpi (dots per inch) for A3 size comprises a print head including 60,000 thyristors in the light emitting portion, a serious image defect will be caused even if only one current supply line for the thyristors in a light-emitting portion is broken. Therefore, a high reliability is required for respective thyristors in the light-emitting portion, resulting in a cost up of a print head.

The reason why an abnormal transfer operation is caused will now be described hereinafter. As shown in FIG. 2A, it is assumed that a cathode line for the thyristor L₅ in a light-emitting portion is broken. FIG. 2B shows High/Low-level of the clock pulses φ1, φ2 and the light-emitting signal φ_{I}, turned-on/turned-off state of the thyristors in the transfer portion, and lighted/lighted out state of the thyristors in the light-emitting portion.

As shown in FIG. 2B, it is assumed that when the clock pulse φ1 is at High-level, the clock pulse φ2 is at Low-level, and the light-emitting signal φ_{I} Low-level at the time t₁, the thyristor S₄ in the transfer portion is turned on, and the thyristor L₄ in the light-emitting portion is lighted. At the time t₂, the clock pulse φ1 becomes Low-level, and the light-emitting signal φ_{I} High-level, so that the thyristor S₅ is turned on, and the thyristor L₄ is lighted out. Subsequently, at the time t₃, the clock pulse φ2 becomes High-level, and the thyristor S₄ is turned off. Subsequently, while the light-emitting signal φ_{I} becomes Low-level at the time t₄, the thyristor L₅ connected to the turned-on thyristor S₅ may not be lighted due to the breakage of the line. At this time, one thyristor among the thyristors L₁-L₆ in the light-emitting portion connected to the φ_{I} line 16 is turned on, the gate voltage of the one thyristor having the highest voltage among the gate voltages on the gates g′₁−g′₆.

FIG. 3 shows the variation of voltages of the gates g₄, g₆, g′₄, g′₆ after the time t₂. While the light-emitting signal φ_{I} becomes High-level at the time t₂ to light out the thyristor L₄, the voltages of the gate g′₄ as well as the gate g₄ becomes approximately 0 volts because the clock pulse φ2 is still at Low-level. When the clock pulse φ2 becomes High-level at the time t₃, the thyristor S₄ is also turned off and then the gates g₄ and g′₄ are pulled down through the resistors R_{g4} and Rₚ₄, so that respective voltages of the gates g₄ and g′₄ are decreased at the time constants τ_{g} and τ′_{g} toward the voltage V_{GA} (−5 volts). In FIG. 3, the voltages of the gates g₄ and g′₄ at the time t₄ are designated by g₄ (t₄) and g′4 (t₄), respectively. At this time, the resistance of the gate g′₄ is larger than that of the gate g₄, so that the time constant τ′_{g} becomes larger to cause the rate of voltage decreasing to be slow.

On the other hand, the thyristor S₅ is turned on at the time t₂, so that respective voltages of the gates g₆ and g′₆ become approximately −V_{D} (V_{D} is a forward rising voltage of the coupling diode D). Subsequently, when the light-emitting signal φ_{I} becomes Low-level at the time t₄, respective voltages of the gates g′₄, g′₅ and g′₆ become as follows:
the voltage of the gate g′₄=g′₄(t₄)
the voltage of the gate g′₅=about 0 volts
the voltage of the gate g′₆=g′₆(t₄).
   As the voltage of the gate g′5 is highest, the thyristor L₅ will be lighted in a normal case. However, the thyristor L₅ may not be lighted because the cathode line for the thyristor L₅ is broken. In this case, the thyristor having the higher voltage between the gate voltage g′₄(t₄) and g′₆(t₄) is lighted. As g′₄(t₄)>g′₆(t₄) in FIG. 3, the thyristor L₄ is lighted again. At this time, the thyristor S5 is turned on in the transfer portion and the thyristor L₄ is lighted in the light-emitting portion, which is an unstable state.

Subsequently, the clock pulse φ2 becomes Low-level at the time t₅. In a normal state, the gate voltage g₆ (t₅) is approximately −V_{D} which is the highest gate voltage among the thyristors connected to the clock pulse φ2 line 14. However, the thyristor L₄ is lighted, so that the voltage of the gate g₄ is a voltage divided by the resistors Rₚ₄ and R_{g4}. In the case of Rₚ₄=5 kΩ, R_{g4}=20 kΩ for example, the voltage g₄ (t₅) is approximately −1 volts. As a result, the light-emitting φ_{I} signal becomes High-level, and then g₄(t₅)>g₆(t₅) at the time t₅ when the thyristor L₄ is lighted out. Consequently, the thyristor S₄ is turned on as shown in FIG. 3B. When the light-emitting signal φ_{I} becomes Low-level at the time t₇, the thyristor L₄ is lighted again. The situation described above is repeated hereinafter, so that the thyristor L₄ is lighted repeatedly and the thyristors after the thyristor L₅ in the light-emitting portion are not lighted. The transfer operation of the thyristors in the light-emitting portion is stopped, resulting in the defect of white stripe in printing.

### SUMMARY OF THE INVENTION

The object of the present invention is to provide a method for driving a self-scanning light-emitting element array in which even if a line in a light-emitting portion is broken, a thyristor neighbored to the failed thyristor having the breakage of the line may be lighted to continue the transfer of a lighted state of the thyristor.

The present invention is a method for driving a self-scanning light-emitting element array including a transfer portion in which a plurality of three-terminal light-emitting thyristors are arrayed in one dimension, gates of neighbored thyristors are connected by a diode respectively, a power supply is connected to each gate of the thyristors through a load resistor, a first and second clock pulses of two phases are alternately supplied to cathodes or anodes of the thyristors; a light-emitting portion in which a plurality of three-terminal light-emitting thyristors are arrayed in one dimension, each gate of the thyristors is connected to a gate of corresponding thyristor in the transfer portion through a resistor, and a light-emitting signal is supplied to cathodes or anodes of the thyristors.

According to the first aspect of the present invention, the method comprises the steps of:
turning on the thyristors in the transfer portion sequentially by the two-phase clock pulses;
lighting the thyristor in the light-emitting portion corresponding to the turned-on thyristor in the transfer portion by the light-emitting signal;
a first time period is provided, during which turned-on states of neighbored two thyristors are overlapped when the turned-on state is transferred in the transfer portion by the two-phase clock pulses;
a second time period is provided after the first time period, during which the thyristor in the light-emitting portion corresponding to the turned-on thyristor in the transfer portion is lighted by the light-emitting signal;
a third time period is provided after the second time period, during which a turned-off thyristor back to the turned-on thyristor in the transfer portion is turned on as well as the lighted thyristor in the light-emitting portion is lighted out; and
the second time period is a time period having a length in which when a thyristor to be lighted in the light-emitting portion is not lighted due to the breakage of a line, a thyristor back to the failed thyristor due to the breakage of the line is lighted.

According to the second aspect of the present invention, the method comprises the steps of:
turning on the thyristors in the transfer portion sequentially by the two-phase clock pulses;
lighting the thyristor in the light-emitting portion corresponding to the turned-on thyristor in the transfer portion by the light-emitting signal;
a first time period is provided, during which turned-on states of neighbored two thyristors are overlapped when the turned-on state is transferred in the transfer portion by the two-phase clock pulses;
a second time period is provided after the first time period, during which the thyristor in the light-emitting portion corresponding to the turned-on thyristor in the transfer portion is lighted by the light-emitting signal;
a third time period is provided after the second time period, during which the lighted thyristor in the light-emitting portion is lighted out;
a fourth time period is provided after the third time period, during which a thyristor back to the turned-on thyristor in the transfer portion is turned on; and
the fourth time period is a time period having a length in which when a thyristor to be lighted in the light-emitting portion is not lighted due to the breakage of a line, a thyristor back to the failed thyristor due to the breakage of the line is lighted.

### BRIEF DESCRIPTION OF THE DRAWINGS

FIG. 1A shows an equivalent circuit diagram of a conventional self-scanning light emitting array.

FIG. 1B shows the waveforms illustrating the operation of the self-scanning light-emitting element array in FIG. 1A.

FIG. 2A shows an equivalent circuit diagram of a self-scanning light emitting array in which a cathode line for the thyristor L₅ in a light-emitting portion is broken.

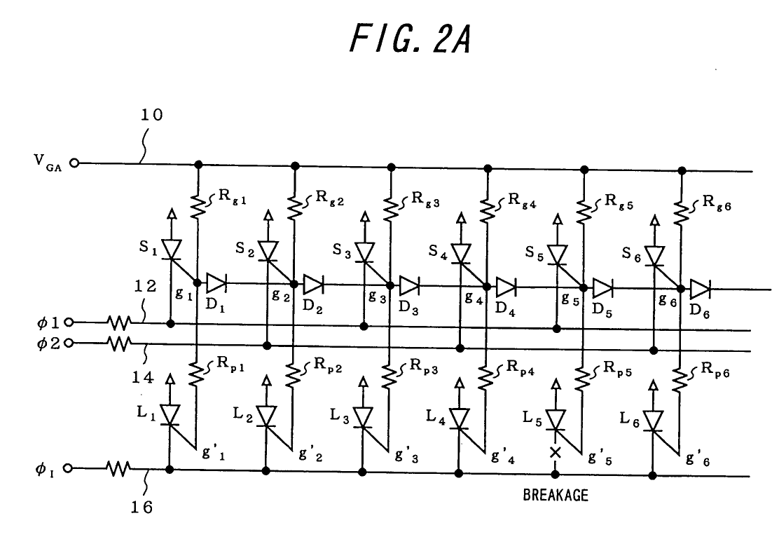

FIG. 2B shows the waveforms illustrating the operation of the self-scanning light-emitting element array in FIG. 2A.

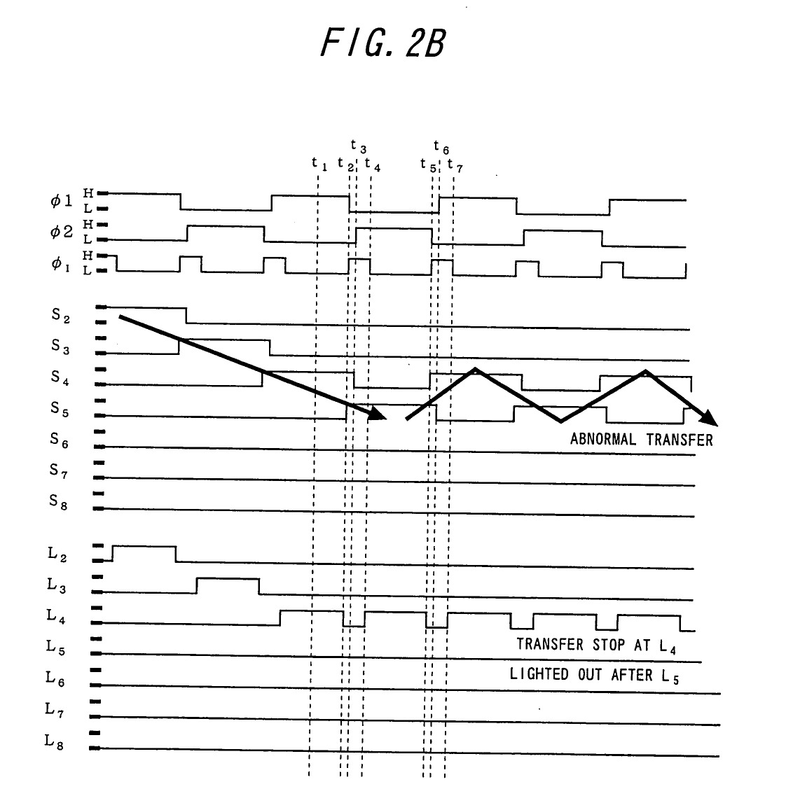

FIG. 3 shows the waveforms for illustrating the stop of transfer operation at the thyristor L₄ in the light-emitting portion in the self-scanning light-emitting element array in FIG. 2A.

FIG. 4 shows the waveforms for illustrating the drive method in the embodiment 1.

FIG. 5 shows the waveforms for illustrating the situation in which the thyristor L₆ is lighted in place of the thyristor L₅ in the light-emitting portion.

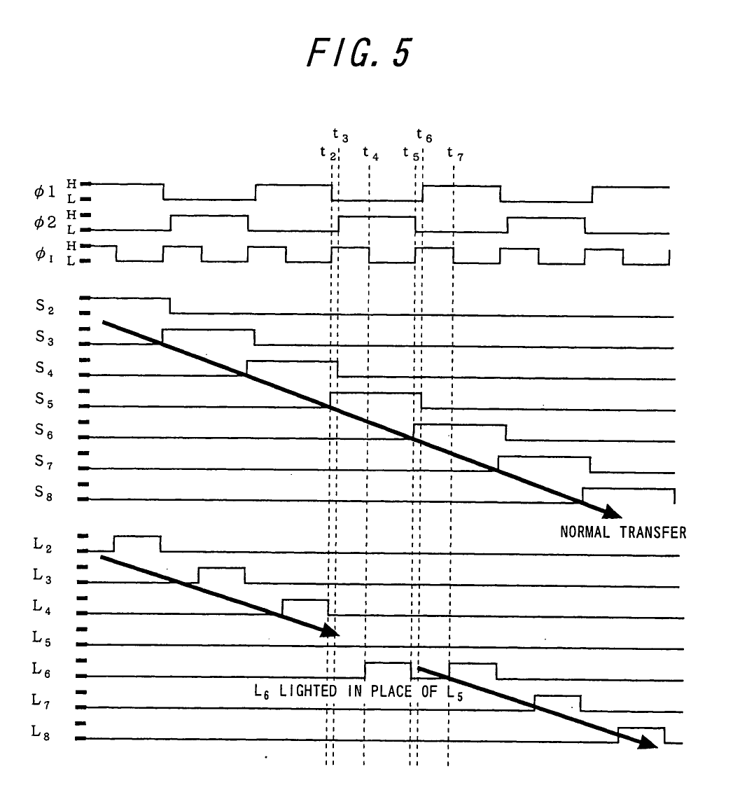

FIG. 6 shows the waveforms for illustrating the drive method in the embodiment 2.

FIG. 7 shows the waveforms for illustrating the situation in which the thyristor L₆ is lighted in place of the thyristor L₅ in the light-emitting portion.

### BEST MODE FOR CARRYING OUT THE INVENTION

An embodiment in accordance with the present invention will now be described for an anode common type using a P-type substrate. It is noted that the present invention may be applied to a cathode common type accompanying with a suitable modification.

Instead of the failed thyristor having a broken line in the light-emitting portion, the thyristor prior to or back to the failed thyristor is lighted to allow a normal operation hereinafter. Therefore, the total number of lighted thyristors is not varied and the position to be lighted is shifted only one dot from the original position, resulting in a less remarkable defect.

There are following two methods to realize the normal operation.
(1) The time period τ_{b}(=t₄−t₃) is selected to be equal to or larger than the time period τ_{b}. As a result, when the breakage of a line is caused, the thyristor Lₙ₊₁ back to the failed thyristor Lₙ having the broken line may be necessarily lighted. It is noted that τ_{b} is the time period required for the voltage of the gate g′ₙ₊₁ of the thyristor Lₙ₊₁ becoming larger than the voltage of the gate g′ₙ₋₁ of the thyristor Lₙ₋₁.
(2) The time period t_{c} is provided between the time when the light-emitting signal φ_{I} becomes High-level and the time when both of the clock pulses φ1 and φ2 become Low-level, t_{c} being larger than the time period τ_{c}. As a result, even if the breakage of a line is caused and the thyristor Lₙ₋₁ prior to the failed thyristor Lₙ having the broken line is lighted in place of the thyristor Lₙ, the lightening of the thyristors after the thyristor Lₙ₊₁ may be transferred normally. It is note that τ_{c} is the time period required for the voltage of the gate gₙ₊₁ of the thyristor Sₙ₊₁ becoming larger than the voltage of the gate gₙ₋₁ of the thyristor Sₙ₋₁ at the timing when both of the clock pulses φ1 and φ2 become Low-level.

### Embodiment 1

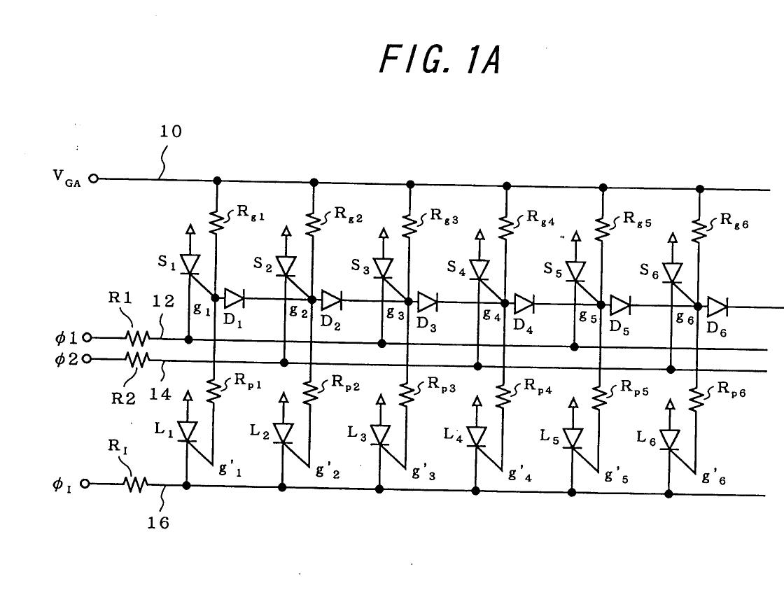

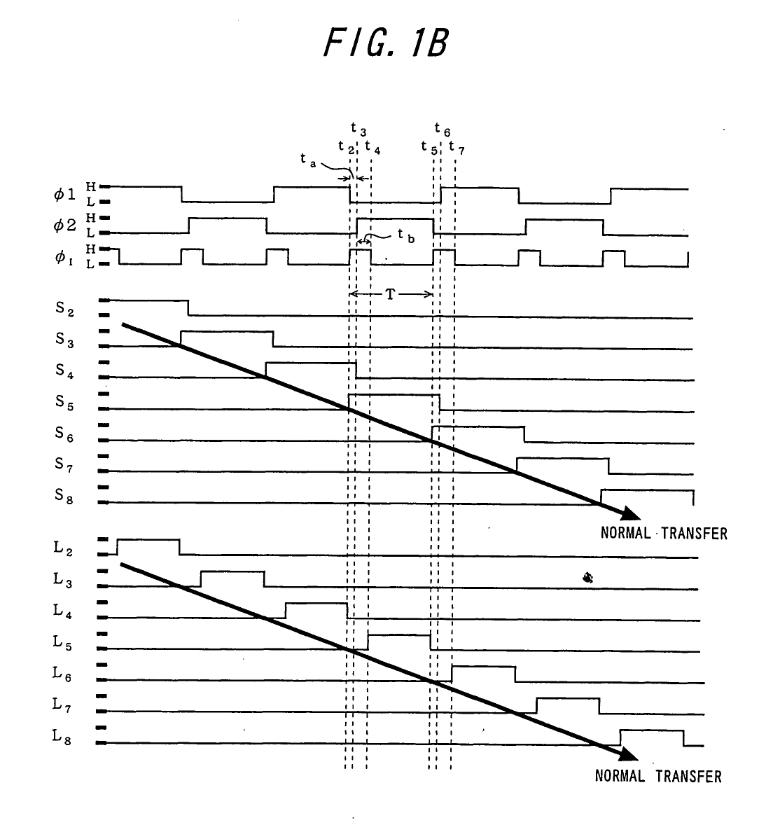

The present embodiment is on the basis of the method (1) described above. In the conventional waveforms shown in FIG. 1B, the length of the time period t_{b} is selected to be shortest for the normal operation of thyristors in the light-emitting portion. If the time period t_{b} is selected to be larger than b which, in the case of the failed thyristor being the thyristor Lₙ, is the time period required for the voltage of the gate g′ₙ₊₁ of the thyristor Lₙ₊₁ back to the thyristor Lₙ becoming larger than the voltage of the gate g′ₙ₋₁ of the thyristor Lₙ₋₁ prior to the thyristor Lₙ, the thyristor Lₙ₊₁ back to the failed thyristor Lₙ may be necessarily lighted.

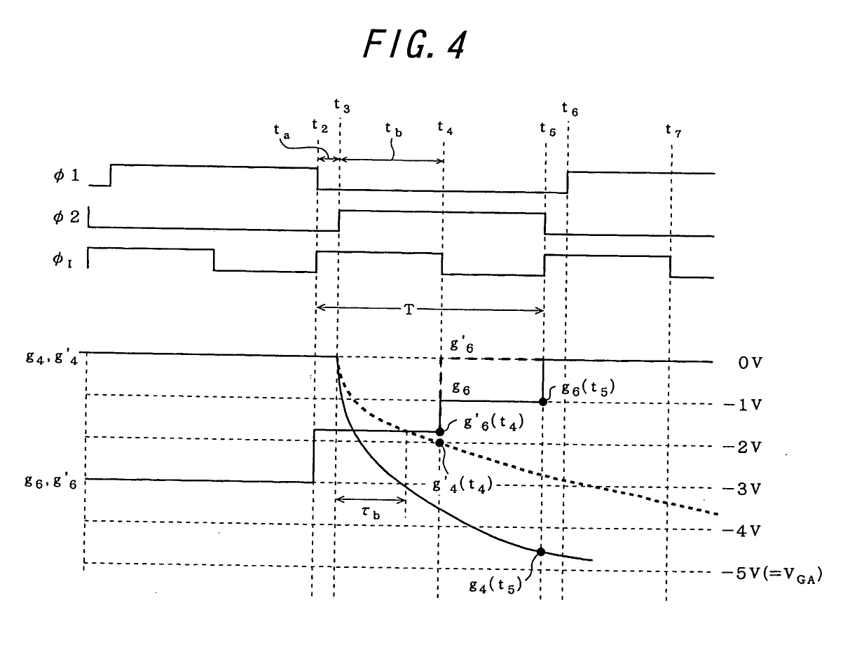

FIG. 4 shows the waveforms of the clock pulses φ1, φ2 and the light-emitting signal φ_{I}. While the transfer period T=t₅−t₂=500 ns, the time period tₐ=t₃−t₂=20 ns, the time period t_{b}=t₄−t₃=20 ns, V_{GA}=−5 volts, High-level voltage=0 volts, and Low-level voltage=−5 volts in the waveforms in FIG. 1B, the time period t_{b} is spread to 80 ns in the waveforms in FIG. 4. Thereby, g′₄(t₄)<g′₆(t₄) at the time t₄, so that the thyristor L₆ may be lighted in place of the failed thyristor L₅.

When the subsequent thyristor S₆ in the transfer portion is intended to be turned on at the time t₅, the gate voltage g₆ (t₅) of the thyristor S₆ at the time t₅ is the highest voltage among the gate voltages of the thyristors in the transfer portion connected to the φ2 line 14, so that the thyristor S₆ may be turned on in order. As a result, the lightening of the thyristors after the thyristor L₆ may be transferred normally.

According to the waveforms shown in FIG. 4, when an image having a middle degree of concentration is outputted, a white stripe may be observed but it is not so remarkable. This is because that a white stripe corresponding to one dot is buried in an entire black area, and an image is an area gray scale in a low degree of concentration so that an effect due to the shift of one dot data is less.

### Embodiment 2

The present embodiment is on the basis of the method (2) described above. A time period t_{c} is provided between the time when the light-emitting signal φ_{I} becomes High-level and the time when both of the clock pulses φ1 and φ2 are at Low-level. The time period t_{c} is selected to be larger than τ_{c} which is a time period required for the voltage of the gate gₙ₊₁ of the thyristor Sₙ₊₁ becoming larger than the voltage of the gate gₙ₋₁ of the thyristor Sₙ₋₁ in the transfer portion, so that the lighting of the thyristors after the thyristor Lₙ₊₁ may be transferred normally.

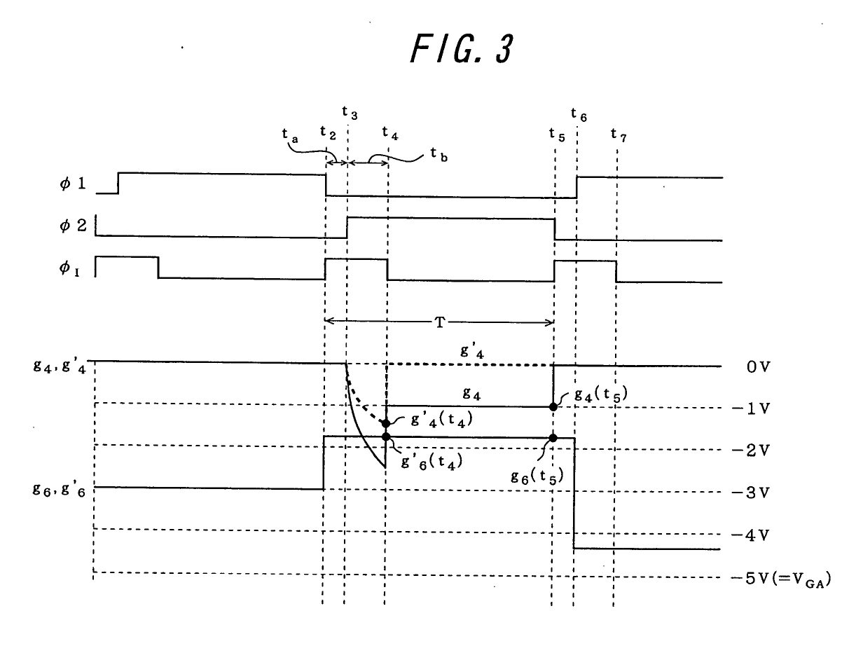

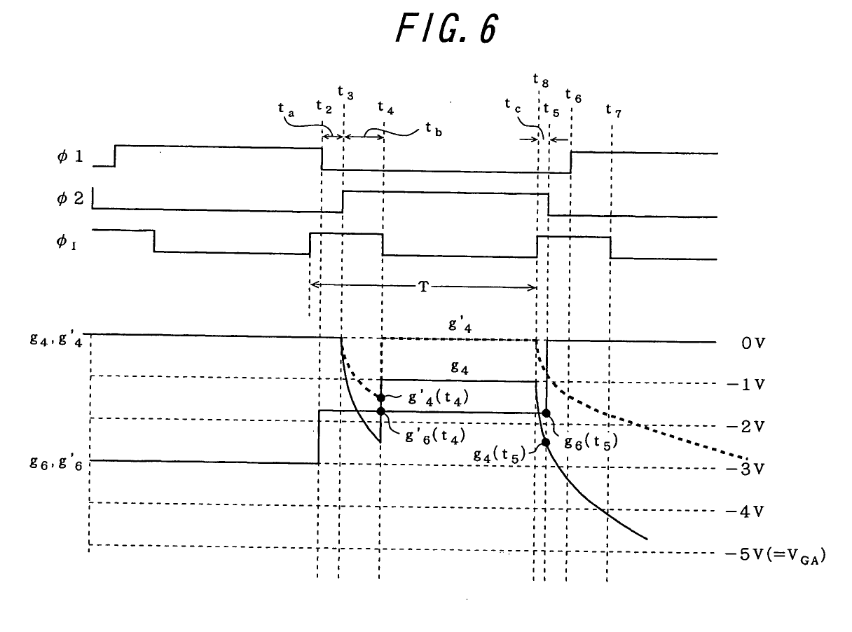

FIG. 6 shows the waveforms of the clock pulses φ1, φ2 and the light-emitting signal φ_{I}. The waveforms are the same as that in FIG. 3 except that the time when the light-emitting signal φ_{I} becomes High-level is caused to be faster by tc in comparison with the light-emitting signal φ_{I} shown in FIG. 3.

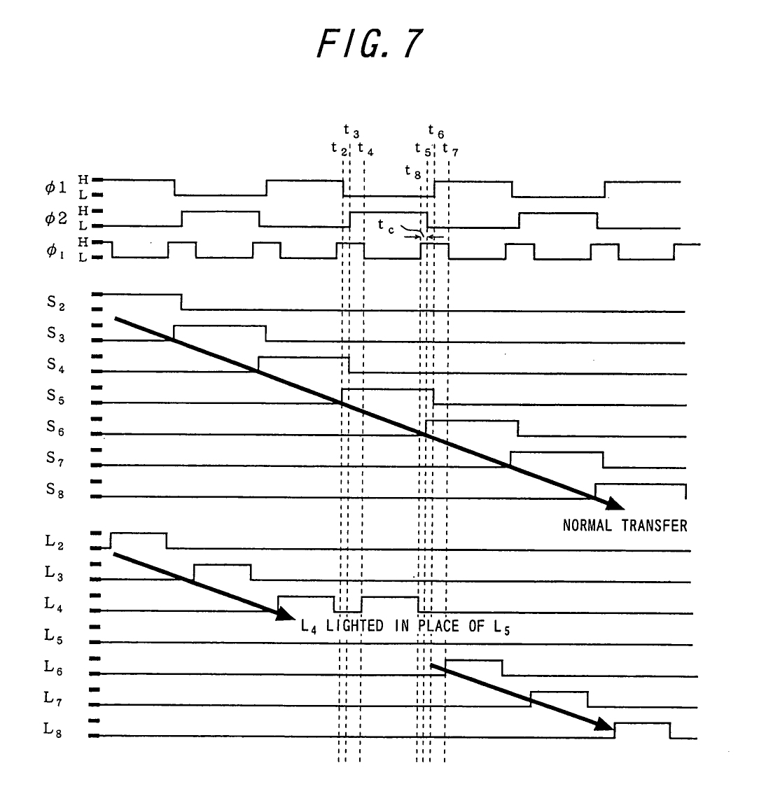

As illustrated with reference to the waveforms in FIG. 3, g′₄(t₄)>g′₆(t₄) at the time t₄ as in the conventional waveforms. Therefore, the thyristor L₄ is lighted again in place of the failed thyristor L₅ in the light portion, and is lighted out at the time t₅ as shown in FIG. 7. Hereinafter, the clock pulse φ₂ becomes Low-level at the time t₆ after the lapse of t_{c}=t₅−t₈, so that g₆(t₅)>g₄(t₅). As a result, the thyristor S₆ is turned on subsequently to the thyristor S₅, and the thyristor L₆ is lighted to implement the normal transfer operation.

In the present embodiment, the difference between the gate voltages g₄(t₈) and g₆(t₈) at the time t₈ is small, so that it is allowable that a short time period t_{c} is provided. The normal transfer operation is possible by t_{c}=20 ns in the waveforms shown in FIG. 6.

In the present embodiment 2, the time period during which the thyristor is lighted may be extended by 40 ns and the light exposure may be increased by approximately 10% in comparison with the embodiment 1.

The present invention may be applied to an optical writing head using a light-emitting element array chip. Also, the present invention is preferable for an optical printer and copy machine because the life time of an optical writing head is extended and the maintenance thereof may easily be implemented.

1. A method for driving a self-scanning light-emitting element array including a transfer portion in which a plurality of three-terminal light-emitting thyristors are arrayed in one dimension, gates of neighbored thyristors are connected by a diode respectively, a power supply is connected to each gate of the thyristors through a load resistor, a first and second clock pulses of two phases are alternately supplied to cathodes or anodes of the thyristors; a light-emitting portion in which a plurality of three-terminal light-emitting thyristors are arrayed in one dimension, each gate of the thyristors is connected to a gate of corresponding thyristor in the transfer portion through a resistor, and a light-emitting signal is supplied to cathodes or anodes of the thyristors; the method comprising the steps of:
turning on the thyristors in the transfer portion sequentially by the two-phase clock pulses;
lighting the thyristor in the light-emitting portion corresponding to the turned-on thyristor in the transfer portion by the light-emitting signal;
a first time period is provided, during which turned-on states of neighbored two thyristors are overlapped when the turned-on state is transferred in the transfer portion by the two-phase clock pulses;
a second time period is provided after the first time period, during which the thyristor in the light-emitting portion corresponding to the turned-on thyristor in the transfer portion is lighted by the light-emitting signal;
a third time period is provided after the second time period, during which a turned-off thyristor back to the turned-on thyristor in the transfer portion is turned on as well as the lighted thyristor in the light-emitting portion is lighted out; and
the second time period is a time period having a length in which when a thyristor to be lighted in the light-emitting portion is not lighted due to the breakage of a line, a thyristor back to the failed thyristor due to the breakage of the line is lighted.

2. The method according to claim 1, wherein the second time period is determined by the variation of the gate voltages of the thyristor back to the failed thyristor and the thyristor prior to the failed thyristor.

3. A method for driving a self-scanning light-emitting element array including a transfer portion in which a plurality of three-terminal light-emitting thyristors are arrayed in one dimension, gates of neighbored thyristors are connected by a diode respectively, a power supply is connected to each gate of the thyristors through a load resistor, a first and second clock pulses of two phases are alternately supplied to cathodes or anodes of the thyristors; a light-emitting portion in which a plurality of three-terminal light-emitting thyristors are arrayed in one dimension, each gate of the thyristors is connected to a gate of corresponding thyristor in the transfer portion through a resistor, and a light-emitting signal is supplied to cathodes or anodes of the thyristors; the method comprising the steps of:
turning on the thyristors in the transfer portion sequentially by the two-phase clock pulses;
lighting the thyristor in the light-emitting portion corresponding to the turned-on thyristor in the transfer portion by the light-emitting signal;
a first time period is provided, during which turned-on states of neighbored two thyristors are overlapped when the turned-on state is transferred in the transfer portion by the two-phase clock pulses;
a second time period is provided after the first time period, during which the thyristor in the light-emitting portion corresponding to the turned-on thyristor in the transfer portion is lighted by the light-emitting signal;
a third time period is provided after the second time period, during which the lighted thyristor in the light-emitting portion is lighted out;
a fourth time period is provided after the third time period, during which a thyristor back to the turned-on thyristor in the transfer portion is turned on; and
the fourth time period is a time period having a length in which when a thyristor to be lighted in the light-emitting portion is not lighted due to the breakage of a line, a thyristor back to the failed thyristor due to the breakage of the line is lighted.

4. The method according to claim 3, wherein the fourth time period is determined by the variation of the gate voltages of the thyristor back to the failed thyristor and the thyristor prior to the failed thyristor.
